(19) United States
(12) Patent Application Publication
(10) Pub. No.: US 2023/0131403 A1
(43) Pub. Date: Apr. 27, 2023

(54) INTEGRATED CIRCUIT STRUCTURE WITH SPACER SIZED FOR GATE CONTACT AND METHODS TO FORM SAME

(71) Applicant: GlobalFoundries U.S. Inc., Malta, NY (US)

(72) Inventors: David C. Pritchard, Glenville, NY (US); Hongru Ren, Mechanicville, NY (US); Zhixing Zhao, Dresden (DE)

(21) Appl. No.: 17/452,175

(22) Filed: Oct. 25, 2021

(51) Int. Cl. H01L 29/423; H01L 29/49; H01L 29/66; H01L 29/417; H01L 29/40

(52) U.S. Cl. CPC H01L 29/42364; H01L 29/4991; H01L 29/66553; H01L 29/41775; H01L 29/401

(57) ABSTRACT

Embodiments of the disclosure provide an integrated circuit (IC) structure including a gate structure over a semiconductor layer. The gate structure includes a first portion having a first horizontal width, and a second portion laterally adjacent the first portion and having a second horizontal width less than the first horizontal width. A gate contact is on the first portion of the gate structure and is not on the second portion of the gate structure.

### BACKGROUND

The present disclosure provides an integrated circuit (IC) structure with spacers sized for a gate contact, and methods to form the same.

In modern integrated circuits, such as microprocessors, storage devices and the like, a very large number of circuit elements, especially field effect transistors (FETs), are provided and operated on a restricted chip area. FETs come in a variety of different configurations, e.g., planar devices, FinFET devices, nanowire devices, etc. These FET devices are typically operated in a switched mode, that is, these devices exhibit a highly conductive state (on-state) and a high impedance state (off-state). The state of the FET is controlled by a gate electrode, which controls, upon application of an appropriate control voltage, the conductivity of a channel region formed between a drain region and a source region.

During manufacture, a gate contact must be formed to a conductive gate electrode to allow electrical control of the gate electrode during operation. As device size and scale continue to shrink, gate electrodes of smaller surface area have become more common. Vertical misalignment between the gate contact and gate electrode thereunder can possibly interfere with a device's operability. Some techniques avoid this problem by increasing lateral separation between the gate electrode and the channel, but this may not be feasible in some product layouts.

### SUMMARY

The illustrative aspects of the present disclosure are designed to solve the problems herein described and/or other problems not discussed.

Embodiments of the disclosure provide an integrated circuit (IC) structure including: a gate structure over a semiconductor layer, the gate structure including: a first portion having a first horizontal width, and a second portion laterally adjacent the first portion and having a second horizontal width less than the first horizontal width; and a gate contact on the first portion of the gate structure, wherein the gate contact is not on the second portion of the gate structure.

Further embodiments of the disclosure provide an integrated circuit (IC) structure including: a gate structure over a semiconductor layer, the gate structure including a gate electrode between a first inner spacer and a second inner spacer; an outer spacer over the semiconductor layer and horizontally adjacent the second inner spacer; and a gate contact on the gate electrode, the first inner spacer, the second inner spacer, and the outer spacer, the gate contact including a first vertical sidewall over the first inner spacer and a second vertical sidewall over the outer spacer.

Additional embodiments of the disclosure provide a method of forming an integrated circuit structure, the method including: forming a gate structure over a semiconductor layer, the gate structure including: a first portion having a first horizontal width, and a second portion laterally adjacent the first portion and having a second horizontal width less than the first horizontal width; and forming a gate contact on the first portion of the gate structure, such that the gate contact is not on the second portion of the gate structure.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of an initial structure to be processed according to embodiments of the disclosure.

FIG. 2 shows a top-down view of the initial structure according to embodiments of the disclosure.

FIG. 3 shows a cross-sectional along line 3-3 of FIG. 2 of removing an outer spacer to create openings adjacent a gate structure according to embodiments of the disclosure.

FIG. 4 shows a cross-sectional view of forming a dielectric on the structure to produce air gaps within the openings according to embodiments of the disclosure.

FIG. 5 shows a cross-sectional view of removing portions of the dielectric and adjacent semiconductor material to define source/drain (S/D) regions according to embodiments of the disclosure.

FIG. 6 shows a cross-sectional view of forming silicide regions on the S/D regions and a gate conductor on the gate according to embodiments of the disclosure.

FIG. 7 shows a plan view of an integrated circuit (IC) structure according to embodiments of the disclosure.

FIG. 8 shows a first partial cross-sectional view of the IC structure viewed from line 8-8 of FIG. 7.

FIG. 9 shows a partial second cross-sectional view of the IC structure viewed from line 9-9 of FIG. 7.

FIG. 10 shows a plan view of an integrated circuit (IC) structure according to further embodiments of the disclosure.

FIG. 11 shows a first partial cross-sectional view of the IC structure viewed from line 11-11 of FIG. 10.

FIG. 12 shows a second partial cross-sectional view of the IC structure viewed from line 12-12 of FIG. 10.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure provide an integrated circuit (IC) structure with spacers for coupling a gate contact to a gate electrode, and methods to form the same. In some cases, embodiments of the disclosure include a gate structure with a spacer of wider horizontal width below the gate contact, and a smaller horizontal spacer width elsewhere. Specifically, the gate structure may include a first portion having a first horizontal width, and a second portion laterally adjacent the first portion and having a second horizontal width less than the first horizontal width. The gate contact may be on the first portion of the gate structure but is not on the second portion of the gate structure. In other cases, the gate structure may include an additional spacer that is located on one side of the gate structure but not located on the opposite side of the gate structure.

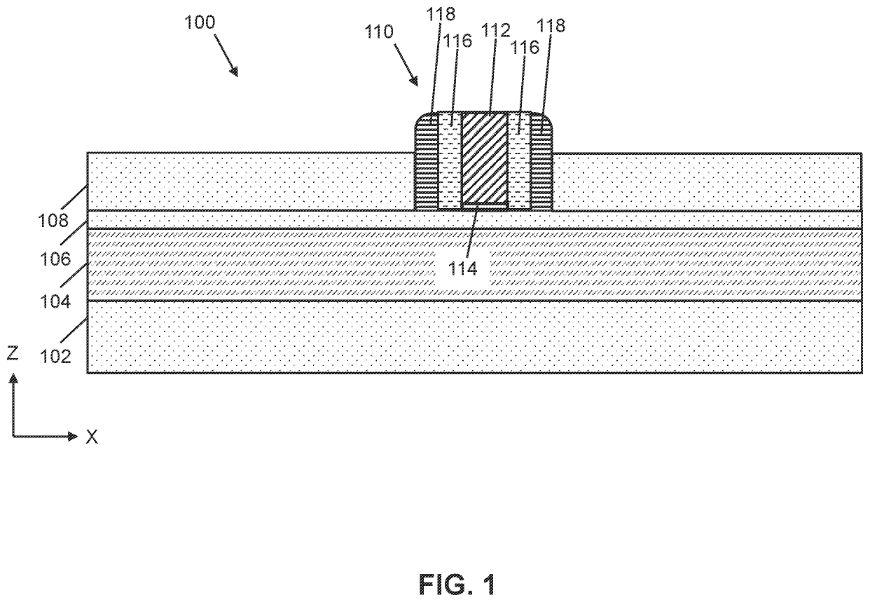

Referring to FIG. 1, embodiments of the disclosure provide methods to form an IC structure. FIG. 1 illustrates an initial structure 100 (simply “structure” hereafter) capable of being processed to form an IC structure according to embodiments of the disclosure. Structure 100 may be formed on a substrate 102 including, e.g., one or more semiconductor materials. Substrate 102 may include but is not limited to silicon, germanium, silicon germanium, silicon carbide, or any other common IC semiconductor substrates. A portion or entire semiconductor substrate 102 may be strained. Additionally, various conductive particles (“dopants”) may be introduced into substrate 102 via a process known as “pre-doping” of substrate 102.

An insulative layer 104, also known in the art as a “buried oxide,” “buried insulator,” or “BOX” layer, can be located on substrate 102. Insulative layer 104 may be composed of one or more oxide compounds, and/or any other currently known or later-developed electrically insulative substances. Insulative layer 104 may be sized as narrow as possible to provide better interaction with semiconductor materials formed thereon, and in various embodiments may have a thickness that is at most approximately twenty-five nanometers (nm). Insulative layer 104 may include, e.g., silicon nitride (Si₃N₄), silicon oxide (SiO₂), fluorinated SiO₂ (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, a spin-on silicon-carbon containing polymer material, near frictionless carbon (NFC), or layers thereof.

Structure 100 can include one or more sets of semiconductor material on an IC structure, including various portions of a transistor structure. In some cases, embodiments of the disclosure may be implemented on a semiconductor on insulator (SOI) substrate 106 located over buried insulative layer 104. Although SOI semiconductor material is illustrated as an example, embodiments of the disclosure may be formed on any type of semiconductor region (e.g., bulk semiconductor material, FDSOI structures, fin-type field effect transistors (FinFETs), semiconductor nanosheets, etc.) without significant modifications.

Initial structure 100 may include one or more epitaxial semiconductor regions 108 on portions of SOI substrate 106, each of which may have a predetermined height above SOI substrate 106. Epitaxial semiconductor regions 108 may be formed, e.g., by epitaxial deposition and/or other currently known or later developed techniques to form a layer of semiconductor material. Deposition or “depositing” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and/or evaporation.

An initial gate structure 110 may also be on SOI substrate 106 and adjacent epitaxial semiconductor region(s) 108 of structure 100. Initial gate structure 110 may include a gate electrode 112 on which conductive contacts to a transistor may be formed. In other cases, initial gate structure 110 may include placeholder materials (e.g., polycrystalline silicon) for subsequent replacement with electrically conductive materials. For the sake of example, initial gate structure 110 is described as already including conductive materials therein. Each gate electrode 112 may be vertically separated from SOI substrate 106 by a gate dielectric 114 such as, for example, a high dielectric constant (high-K) layer.

Gate dielectric 114 may include any now known or later developed high-K material typically used for metal gates such as but not limited to: metal oxides such as tantalum oxide (Ta₂O₅), barium titanium oxide (BaTiO₃), hafnium oxide (HfO₂), zirconium oxide (ZrO₂), aluminum oxide (Al₂O₃) or metal silicates such as hafnium silicate oxide (Hf_{A1}Si_{A2}O_{A3}) or hafnium silicate oxynitride (Hf_{A1}Si_{A2}O_{A3}N_{A4}), where A1, A2, A3, and A4 represent relative proportions, each greater than or equal to zero and A1+A2+A3+A4 (1 being the total relative mole quantity). Gate electrode 112 may include various metals depending on whether for an n-type finFET or a p-type finFET, but may include, for example: aluminum (A1), zinc (Zn), indium (In), copper (Cu), indium copper (InCu), tin (Sn), tantalum (Ta), tantalum nitride (TaN), tantalum carbide (TaC), titanium (Ti), titanium nitride (TiN), titanium carbide (TiC), TiAlC, TiAl, tungsten (W), tungsten nitride (WN), tungsten carbide (WC), polycrystalline silicon (poly-Si), and/or combinations thereof. Gate electrode 112 and/or gate dielectric 114 can be formed using any appropriate deposition and patterning techniques, and any necessary planarization of last deposited material.

Initial gate structure 110 may include one or more inner spacers 116 adjacent to gate conductor 112 and gate dielectric 114. Inner spacers 116 may be provided as one or more bodies of insulating material formed above SOI substrate 106, e.g., by deposition/etching, thermal growth, etc. Inner spacer(s) 116 may be formed to electrically and physically separate conductive materials such as gate electrode 112 from other components in the eventual IC structure. Inner spacer(s) 116 may include one or more low-K dielectric materials, i.e., dielectric materials with a dielectric constant of at most approximately 3.9. Inner spacer 116, for example, may include one or more insulative oxide and/or nitride materials. In some cases, inner spacer(s) 116 may include one or more insulative materials included in buried insulative layer 104 or a different insulative material.

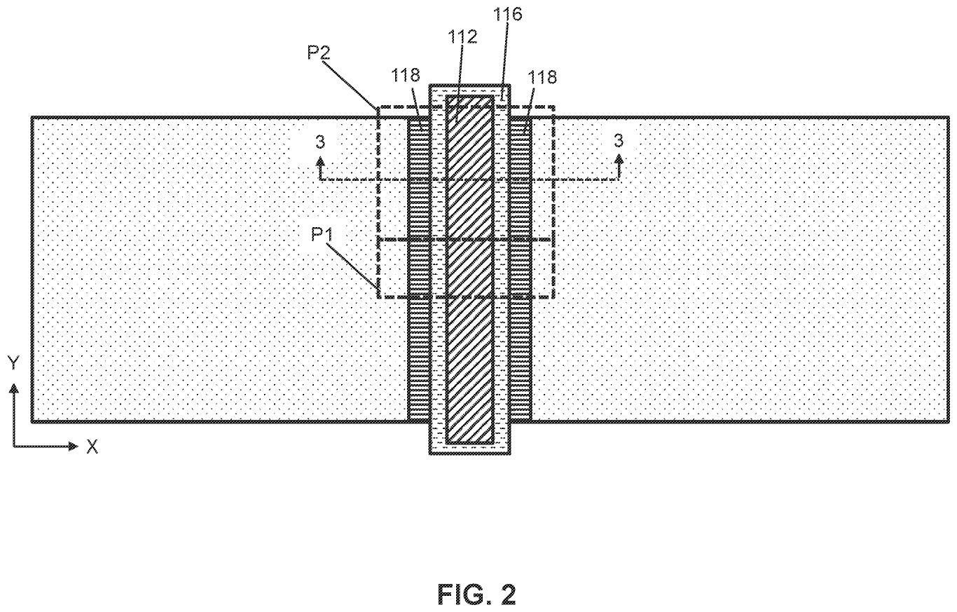

Referring to FIGS. 1 and 2 together, initial gate structure 110 may include a set of outer spacers 118 on SOI substrate 106 and adjacent inner spacer(s) 116, e.g., to define the widest horizontal gate width in the eventual IC structure. Outer spacer(s) 118 may include insulative material(s) that are different from inner spacer(s) 116, e.g., one or more nitride insulators in the case where inner spacer(s) 116 include an oxide insulator. Further processing of structure 100 may include modifying some portions of initial gate structure 110 to remove and replace outer spacer(s) 118, while leaving other portions of initial gate structure 110 (or only outer spacers 118 thereof) intact to produce a gate structure of varying horizontal width. Initial gate structure 110 thus may include a first portion P1 where one or more gate contacts to gate electrode 112 will be formed, and a second portion P2 where no gate contacts to gate electrode 112 will be formed. Further processing according to the disclosure thus may be implemented solely on second portion P2 and possibly without affecting the same components within first portion P1. In some cases, a protective mask (not shown) may be formed over first portion P1 to protect components thereof from being affected by further processes.

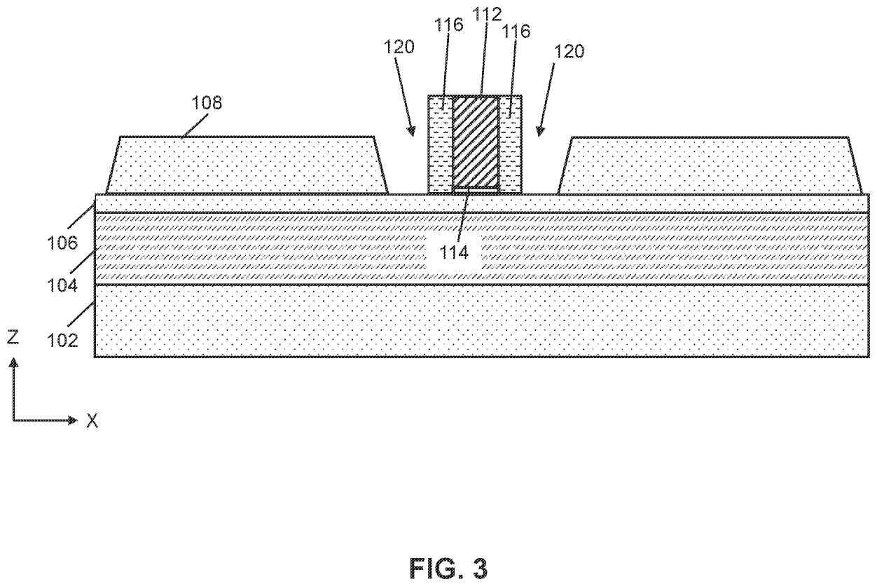

Turning to FIG. 3, portions of outer spacer 118 and epitaxial semiconductor layer 108 may be removed to form a set of openings 120 adjacent initial gate structure 110. Any currently known or later developed targeted removal process, e.g., a reactive ion etch (RIE) may be performed to expose SOI substrate 106 beneath the removed portions of epitaxial semiconductor layer 108 and outer spacer 118. A mask (not shown) may be formed over other portions of outer spacer 118 (e.g., those in first portion P1 (FIG. 2)) to prevent other portions of outer spacer 118 from also being removed. The removing of epitaxial semiconductor layer 108 and outer spacer 118 may decrease the horizontal width of initial gate structure 110, such that the exterior sidewalls of inner spacer(s) 116 define its outer periphery once opening(s) 120 is/are formed.

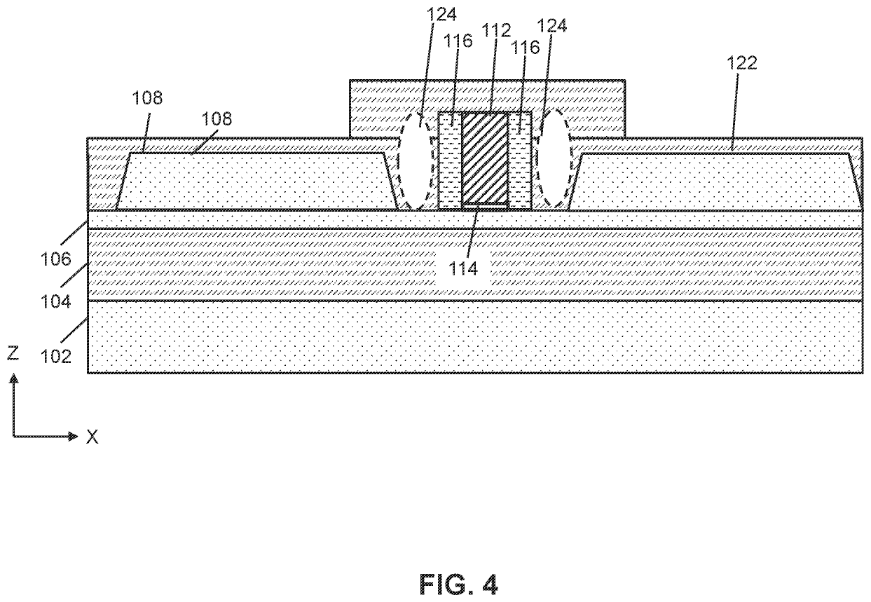

FIG. 4 depicts the forming of a flowable insulator 122 on epitaxial semiconductor layer 108, gate electrode, 112, and inner spacer(s) 116. Flowable insulator 122 may also be formed to cover the previously formed opening(s) 120 (FIG. 3). Flowable insulator 122 may include, e.g., an oxide or other electrically insulative material capable of being formed in a liquid-based state on existing components. Flowable insulator 122 may be formed by way of flowable chemical vapor deposition (FCVD) processing. FCVD uses an initial conversion of an insulator material such as silicon dioxide (SiO₂) together with an oxidizing ambient such as steam, followed by a high temperature densification anneal (e.g., greater than 900° C.) to produce an insulator material on exposed surfaces. The use of flowable insulator 122 may produce a set of air gaps 124 in narrow spaces between adjacent materials, e.g., due to evaporation under the high temperature conditions. Air gaps 124 may be present alongside inner spacer(s) 116 in the space where opening(s) 120 were formed previously. Portions of flowable insulator 122 may coat the upper surface and sidewalls of epitaxial semiconductor layers 108. Flowable insulator 122 may not include air gaps in other areas, e.g., those above epitaxial semiconductor layer 108, gate electrode, 112, and inner spacer(s) 116.

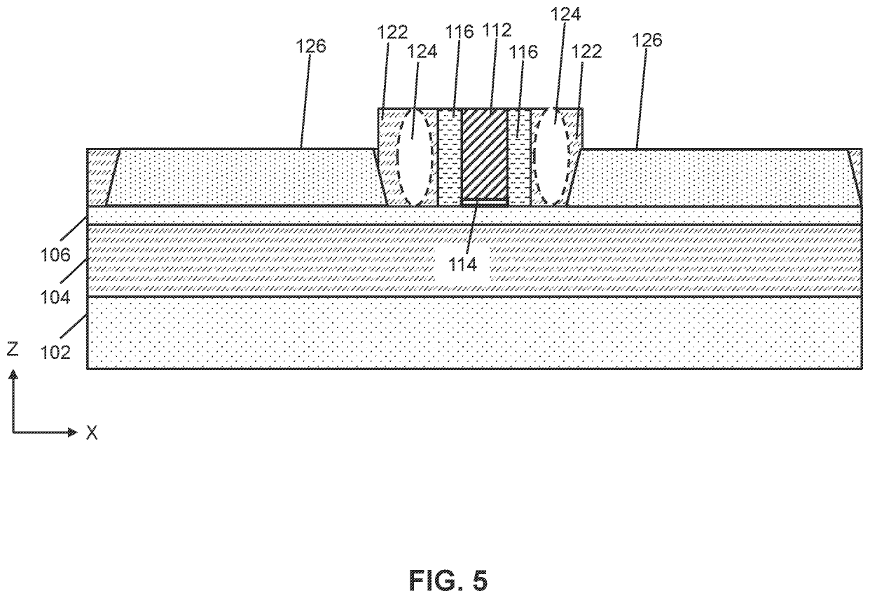

Turning to FIG. 5, further processing may include modifying epitaxial semiconductor layer 108 to define electrically active areas of a transistor for the IC structure. For example, portions of epitaxial semiconductor layer 108 and overlaying portions of flowable insulator 122 may be removed (e.g., by targeted etch) to uncover the upper surface of SOI substrate 106. Remaining portions of semiconductor material horizontally adjacent remaining portions of flowable insulator 122 and the previously formed air gaps 124 may define a set of source/drain (S/D) terminals 126 for a transistor structure. Further processing may include introducing dopants into S/D terminals 126 with a desired polarity and/or dopant concentration to produce electrically active semiconductor regions within all or portions of S/D terminals 126. Portions of flowable insulator 122 may remain intact horizontally between spacer(s) 116 and S/D terminal(s) 126. Moreover, S/D terminals 126 may only be defined adjacent the location of air gap(s) 124, and not in portions of the structure where any gate contacts will be formed.

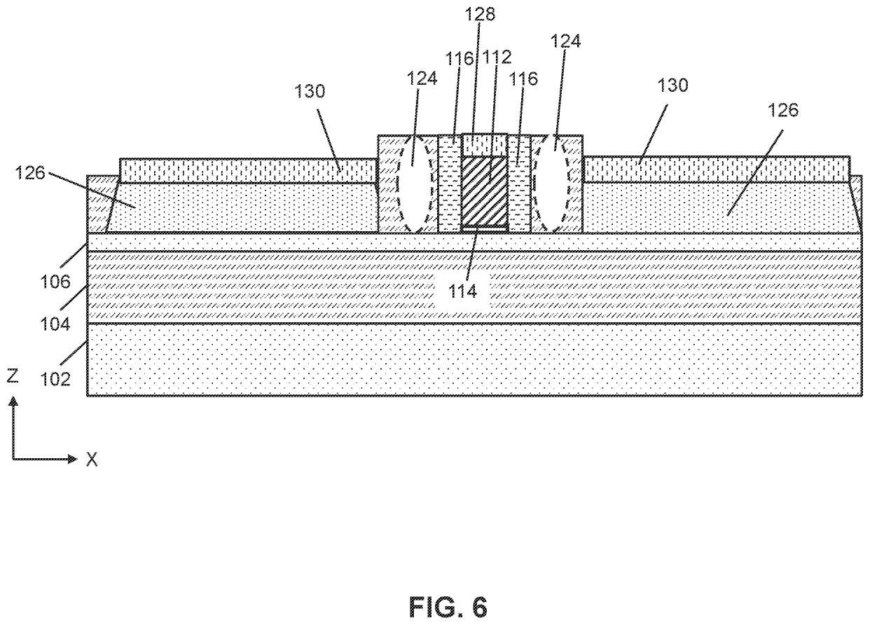

Referring now to FIG. 6, continued processing may include further preparing of the structure for coupling to contacts and overlying device layers. Embodiments of the disclosure may include forming a gate conductor 128 on gate electrode 112. The disclosure also may include forming a set of S/D silicide regions 130 on S/D terminals 126. Gate conductor 128 may be formed, e.g., by recessing and/or otherwise removing a portion of gate electrode 112 and forming a conductive material on the remainder of gate electrode 112. Gate conductor 128 may be one or more metals suitable for coupling to an overlying metal through a direct physical interface (e.g., copper (Cu) and/or other metal wiring materials). In cases where gate electrode 112 includes a doped semiconductor material, gate conductor 128 may include a silicide such as one or more materials discussed herein relative to S/D silicide regions 130.

S/D silicide region(s) 130 may include, e.g., one or more layers of conductive material formed using any now known or later developed technique on underlying semiconductor material (e.g., S/D materials 126). S/D silicide region(s) 130 may be formed, e.g., after the doping of the underlying semiconductor but before the forming of conductive contacts. S/D silicide region(s) 130 may be formed by performing an in-situ pre-clean, depositing a metal such as titanium, nickel, cobalt, etc., annealing to have the metal react with silicon, and removing unreacted metal. S/D silicide region(s) 130 thus may include one or more of tungsten silicide, tungsten nitride, titanium nitride, tantalum nitride, ruthenium oxide, cobalt silicide, and/or nickel silicide, depending on the type of metal deposited and annealed and/or the type of underlying semiconductor material(s). S/D silicide region(s) 130 may cover the upper surface(s) of S/D terminals 126, without being formed on locations that are covered by flowable insulator 122 (e.g., sidewalls of S/D terminals 126).

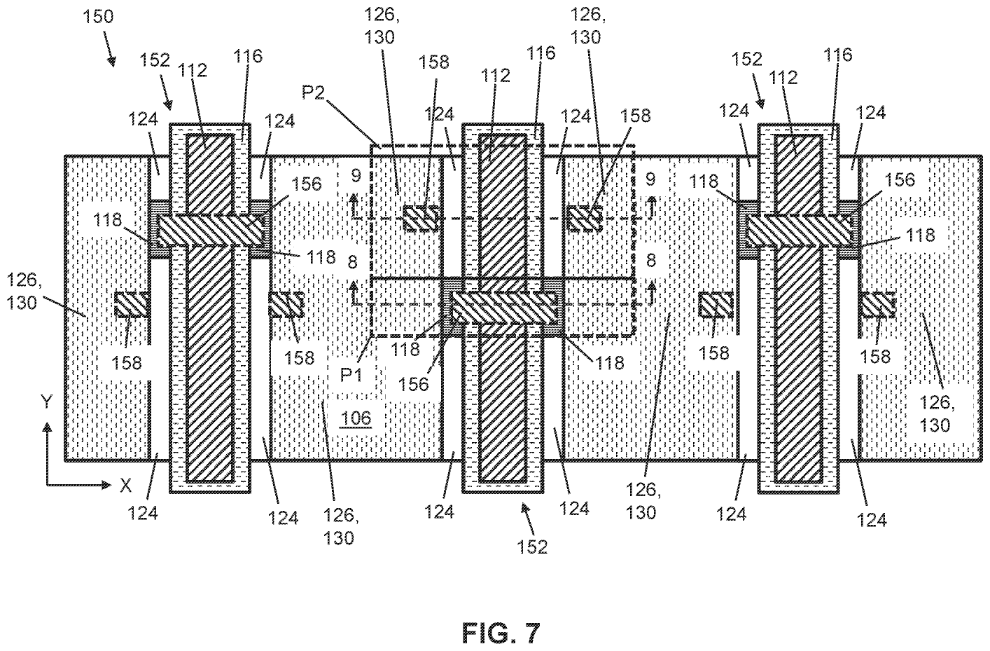

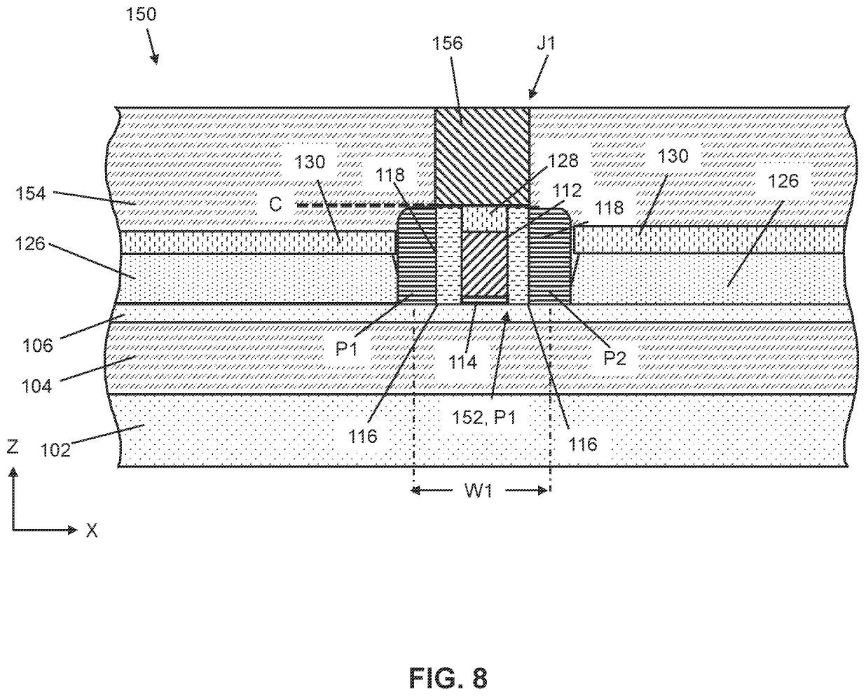

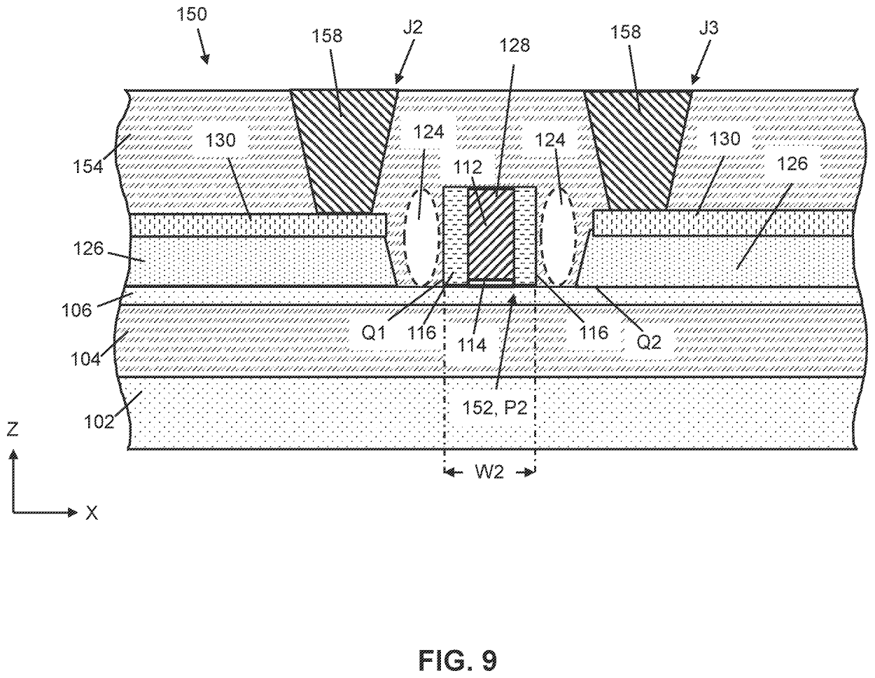

Referring to FIGS. 7-9 together, further processing according to the disclosure may yield an integrated circuit (IC) structure 150 in which the horizontal width of a gate structure 152 varies with respect to length. FIG. 7 provides a plan view of IC structure 150, with view lines 8-8 and 9-9 indicating the perspective for cross-sectional views shown in FIGS. 8 and 9, respectively. Further processing to yield IC structure 150 may include, e.g., forming a dielectric region 154 (visible in FIGS. 8, 9 only) over the previously formed materials to a desired height. Dielectric region 154 may include one or more insulators described herein with respect to buried insulative layer 104, and/or may include any other currently known or later developed insulative material. Dielectric region 154 may physically and electrically separate active components of IC structure 150 from overlying elements. Due to the use of flowable insulator 122 (FIG. 4) to form air gaps 124, residual flowable insulator material surrounding air gaps 124 may stop dielectric material in dielectric region 154 from entering and filling air gap(s) 124.

After dielectric region 154 is formed, a set of openings J1, J2, J3 may be formed within dielectric region 154 and filled with conductive materials, e.g., tungsten, copper, etc., to form gate contact(s) 156 in opening J1 to first portion P1 of gate structure 152 and S/D contacts 158 in openings J2, J3 to second portion P2 of gate structure 152. Contact(s) 156, 158 additionally may include, e.g., refractory metal liners (not shown) to horizontally separate conductive materials of contact(s) 156, 158 from dielectric region 154 and/or other horizontally adjacent materials (not shown). Such liners may include materials such as but not limited to tantalum nitride (TaN) and tantalum; tantalum nitride, tantalum, and cobalt; and magnesium (Mn), or combinations thereof. After contact(s) 156, 158 are formed, IC structure 150 may include gate structure 152 in which first portion P1 has a first horizontal width W1 measured between the outer horizontal peripheries P1, P2 of outer spacers 118, and second portion P2 has a second, smaller horizontal width W2 that is between the outer peripheries Q1, Q2 of inner spacers 116 due to the earlier forming of air gaps 124.

Each air gap 124 may have a horizontal width that is substantially equal (i.e., between 95% and 105%) to the horizontal width of gate structure 152 in first portion P1 thereof. Gate contact 156 is on gate structure 152 only within first portion P1, such that gate contact 156 does not overlie and/or extend vertically into air gaps 124 in second portion P2. Second portion P2 of gate structure 152, in addition, is located horizontally between S/D contacts 158 (FIGS. 7, 9) but is not below any part of gate contact 156. Despite differences in the size of gate structure 152 in each portion P1, P2, SOI substrate 106 may have a substantially uniform dopant concentration, and thus the electrical conductivity of SOI substrate 106 may be substantially uniform regardless of whether they are below first portion P1 or second portion P2 of gate structure 152.

As shown in the cross-sectional view of FIG. 8, gate contact 156 may have a lower surface C that is over gate electrode 112 (including gate conductor 128 thereon), inner spacer 116, and outer spacer 118. Additionally, the horizontal width of gate contact 156 may be greater than that of gate electrode 112 and/or gate conductor 128. Gate contact 156 thus may contact and overlie outer spacers 118, without physically interfacing with any sidewalls of gate structure 152 or adjacent upper surfaces of SOI substrate 106. By comparison, the smaller horizontal width of gate structure 152 in second portion P2 (e.g., as depicted in FIG. 9) may not be as wide as gate contact 156. Gate contact 156 being present only over second portion P1 thus avoids any conductive materials from being positioned within air gaps 124.

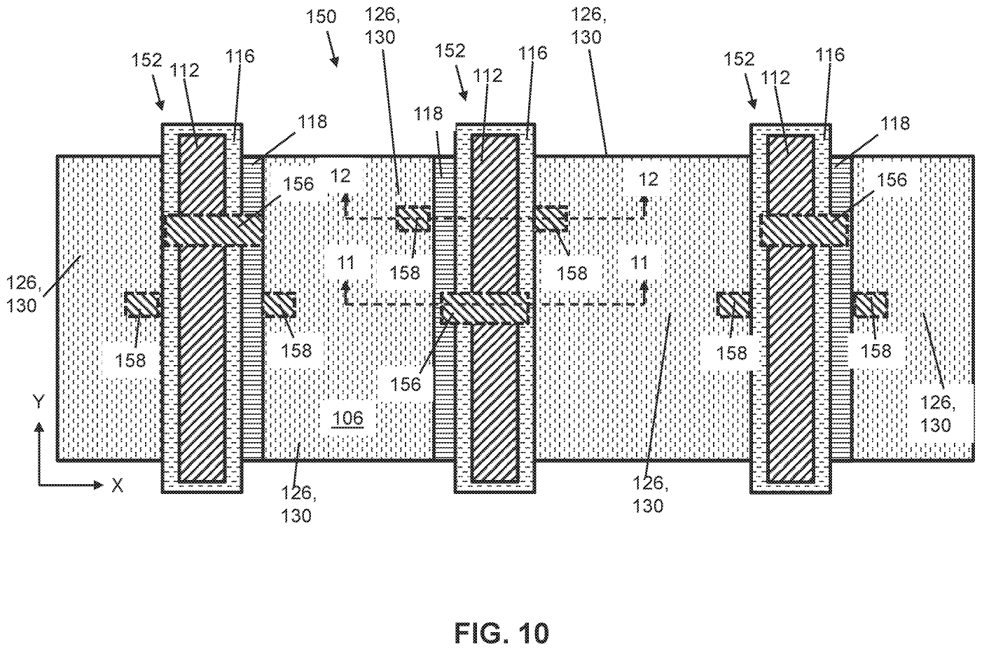

Referring now to FIGS. 10-12, further embodiments of IC structure 150 may include gate structure 152, in which the horizontal width of gate structure 152 between gate electrode 112 and a first outer periphery K1 is different from the width between gate electrode 112 and a second, opposite outer periphery K2. Here, gate structure 152 may include only one outer spacer 118 adjacent one inner spacer 116, such that another inner spacer 116 of gate structure 152 does not have a corresponding outer spacer 118. As discussed herein, such embodiments of gate structure 152 also allow operable coupling between gate electrode 112 and/or gate conductor 128 to gate contact(s) 156 that feature a larger horizontal width.

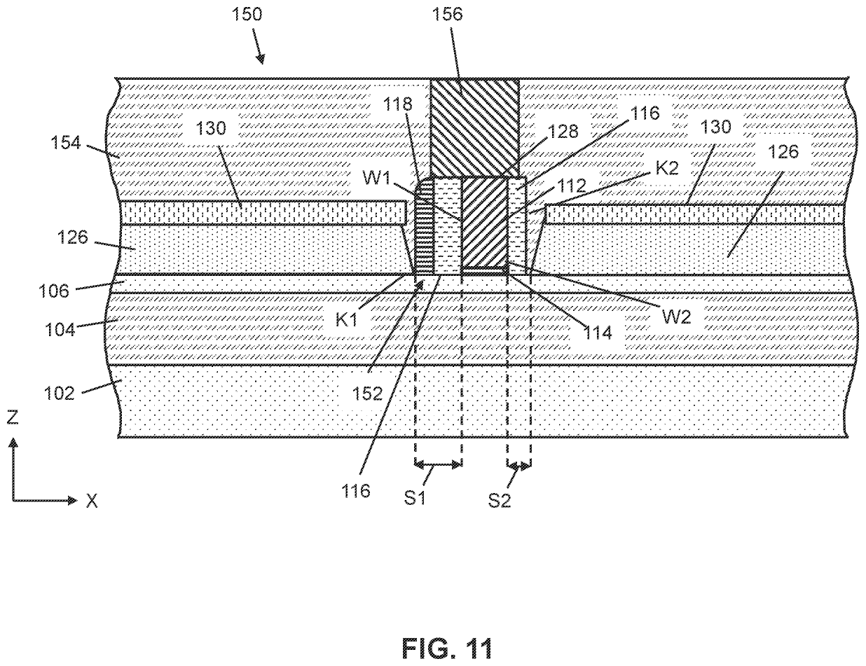

As shown specifically in FIG. 11, a first horizontal separation distance S1 between a sidewall W1 of gate electrode 112 and outer periphery K1 of outer spacer 118 is larger than a second horizontal separation distance S2 between an opposite sidewall W2 of gate electrode 112 and outer periphery K2 of its inner spacer 116. Gate contact 156 may be on gate electrode 112 (including gate conductor 128 thereof), inner spacer 116, and outer spacer 118 such that one of its sidewalls intersects outer spacer 118, while its opposite sidewall intersects inner spacer 116 at the opposing horizontal end of gate structure 152. In this configuration, a lower surface of the gate contact 156 does not physically interface with an upper surface of SOI layer 106 or a sidewall of any spacer(s) 116, 118 thereunder. Thus, gate contact 156 is operable for use on gate structure 152 despite having a horizontal width that is significantly greater than gate electrode 112.

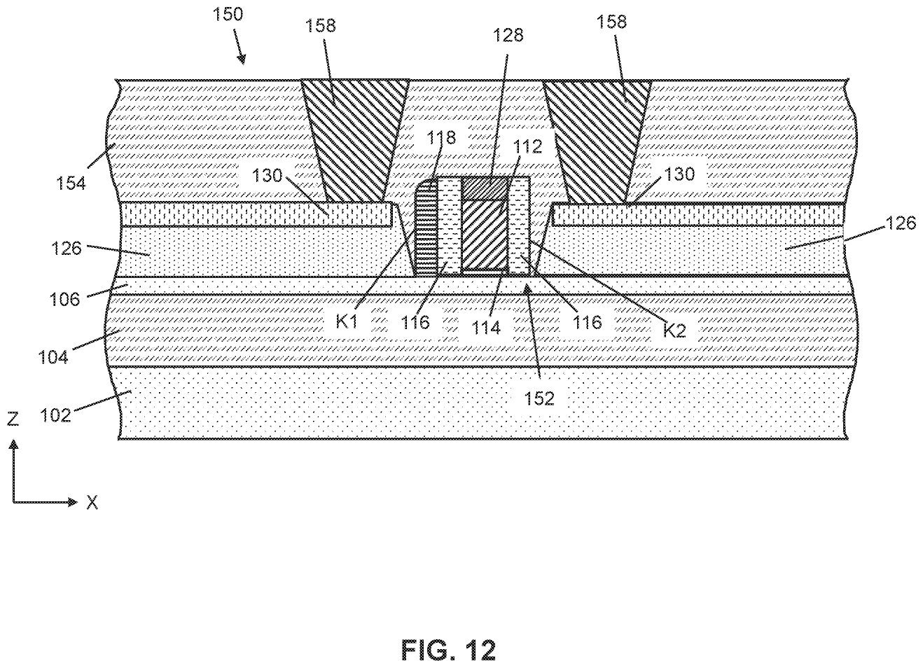

These and other structural aspects of gate structure 152 may also be present between S/D contacts 158 (FIGS. 10, 12). For example, one inner spacer 116 may be horizontally between gate electrode 112 and one S/D region 126, while outer spacer 118 horizontally separates the other inner spacer 116 from the other S/D region 126 on SOI substrate 106. Unlike other implementations discussed herein, the cross-section of gate structure 152 between S/D contacts 158 may be substantially the same as below gate contact 156, with variance in horizontal width arising from an asymmetric size and/or number of spacer(s) 116, 118 in opposing horizontal directions. Outer spacer 118 may be formed adjacent only one inner spacer 116, e.g., by modifying conventional gate fabrication techniques such that a mask or other protective material covers one inner spacer 116, with the other inner spacer being exposed to allow outer spacer 118 formation adjacent to inner spacer 116. It is emphasized that by using outer spacer 118 in gate structure 152, air gaps 124 (FIGS. 4-7) discussed elsewhere herein may be omitted from IC structure 150.

Embodiments of the disclosure may provide various technical and commercial advantages. Embodiments of gate structure 152 discussed herein may be operable for use with gate contact(s) 158 with horizontal widths that are significantly larger than gate electrode 112. Additionally, the presence of outer spacer(s) 118 in targeted locations prevents gate contact(s) 158 from physically interfacing with the sidewalls of gate structure 152 and/or adjacent portions of SOI layer 106. The presence of air gap 124 in certain embodiments provides electrical insulation while preventing gate structure 152 from being wider than desired in portions where gate contact 156 is not present. Additionally, embodiments of the disclosure are particularly suitable for transistors which rely on a “short channel” gate coupling, in which little to no variation in the conductivity of SOI substrate 106 is desired and/or where the length of gate structure 152 should be within strict limits.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a center processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. An integrated circuit (IC) structure comprising:
a gate structure over a semiconductor layer, the gate structure including:
a first portion having a first horizontal width, and
a second portion laterally adjacent the first portion and having a second horizontal width less than the first horizontal width; and
a gate contact on the first portion of the gate structure, wherein the gate contact is not on the second portion of the gate structure.

2. The IC structure of claim 1, further comprising:
a dielectric region on the semiconductor layer and adjacent the gate structure; and
at least one air gap defined within the dielectric region and horizontally adjacent the second portion of the gate structure.

3. The IC structure of claim 2, wherein the first portion of the gate structure includes:
a gate electrode on the semiconductor layer;
an inner spacer on the semiconductor layer horizontally adjacent the gate electrode; and
an outer spacer on the semiconductor layer horizontally adjacent the inner spacer, wherein a horizontal width of the outer spacer is substantially equal to a horizontal width of the at least one air gap.

4. The IC structure of claim 3, wherein a lower surface of the gate contact is over the gate electrode, the inner spacer, and the outer spacer of the first portion of the gate structure.

5. The IC structure of claim 3, wherein a material composition of the outer spacer is different from a material composition of the inner spacer and a material composition of the at least one air gap.

6. The IC structure of claim 1, wherein the second portion of the gate structure is horizontally between a pair of source/drain (S/D) contacts.

7. The IC structure of claim 1, wherein a dopant concentration within the semiconductor layer below the first portion of the gate structure is substantially equal to a dopant concentration within the semiconductor layer below the second portion of the gate structure.

8. The IC structure of claim 1, wherein a lower surface of the gate contact does not physically interface with an upper surface of the semiconductor layer or a sidewall of the first portion of the gate structure.

9. The IC structure of claim 1, wherein the semiconductor layer includes a semiconductor on insulator (SOI) layer on a buried insulative layer.

10. An integrated circuit (IC) structure comprising:
a gate structure over a semiconductor layer, the gate structure including a gate electrode between a first inner spacer and a second inner spacer;
an outer spacer over the semiconductor layer and horizontally adjacent the second inner spacer; and
a gate contact on the gate electrode, the first inner spacer, the second inner spacer, and the outer spacer, the gate contact including a first vertical sidewall over the first inner spacer and a second vertical sidewall over the outer spacer.

11. The IC structure of claim 10, wherein a horizontal separation distance between the gate electrode and an outer periphery of the first inner spacer is less than a horizontal separation distance between the gate electrode and an outer periphery of the outer spacer.

12. The IC structure of claim 10, wherein an outer periphery of the first inner spacer is horizontally adjacent a portion of a first source/drain (S/D) region on the semiconductor layer, and the outer spacer horizontally separates the second inner spacer from a second S/D region on the semiconductor layer.

13. The IC structure of claim 10, wherein a lower surface of the gate contact does not physically interface with an upper surface of the semiconductor layer or a sidewall of the outer spacer.

14. A method of forming an integrated circuit structure, the method comprising:
forming a gate structure over a semiconductor layer, the gate structure including:
a first portion having a first horizontal width, and
a second portion laterally adjacent the first portion and having a second horizontal width less than the first horizontal width; and
forming a gate contact on the first portion of the gate structure, such that the gate contact is not on the second portion of the gate structure.

15. The method of claim 14, further comprising:
forming a dielectric region on the semiconductor layer and adjacent the gate structure; and
forming at least one air gap defined within the dielectric region and horizontally adjacent the second portion of the gate structure.

16. The method of claim 14, wherein forming the gate structure includes:
forming a gate electrode on the semiconductor layer;
forming an inner spacer on the semiconductor layer horizontally adjacent the gate electrode; and
forming an outer spacer on the semiconductor layer horizontally adjacent the inner spacer, wherein a horizontal width of the outer spacer is substantially equal to a horizontal width of the at least one air gap.

17. The method of claim 14, further comprising forming a pair of source/drain (S/D) contacts on the semiconductor layer and horizontally adjacent the second portion of the gate structure.

18. The method of claim 14, further comprising introducing dopants into the semiconductor layer, such that a dopant concentration within the semiconductor layer below the first portion of the gate structure is substantially equal to a dopant concentration within the semiconductor layer below the second portion of the gate structure.

19. The method of claim 14, wherein forming the gate structure includes forming a plurality of gate structures on the semiconductor layer, each of the plurality of gate structures including the first portion and the second portion, wherein the first portion of one of the plurality of gate structures is horizontally aligned with the second portion of another one of the plurality of gate structures.

20. The method of claim 14, further comprising providing the semiconductor layer as a semiconductor on insulator (SOI) layer on a buried insulative layer.
